(19) United States
(12) Patent Application Publication
(10) Pub. No.: US 2026/0133228 A1
(43) Pub. Date: May 14, 2026

(54) Non-Contact Current Sensor Array For High Voltage Electric Power Lines

(71) Applicant: Southern States, LLC, Hampton, GA (US)

(72) Inventors: Jiyuan Fan, Duluth, GA (US); Hua Fan, Cumming, GA (US); Tan Tran, Morrow, GA (US)

(21) Appl. No.: 18/948,378

(22) Filed: Nov. 14, 2024

(51) Int. Cl. G01R 15/18; G01R 19/00

(52) U.S. Cl. CPC G01R 15/181; G01R 19/0092

(57) ABSTRACT

A non-contact current sensor array for high voltage electric power lines provides analog suppression of magnetic coupling from neighboring conductors. In a three-phase example, the sensor array measures magnetic coupling proportional to the current in a selected phase conductor (e.g., Phase-A) of a three-phase power line, while suppressing magnetic coupling from the other phase conductors of the power line (e.g., Phase-B and Phase-C). The sensor array includes a primary sensor in transverse alignment with Phase-A, a first ancillary sensor in radial alignment with Phase-B, a second ancillary sensor in radial alignment with Phase-C. The primary sensor, first ancillary sensor, and second ancillary sensor are electrically connected in series with respective winding turns selected to substantially cancel out magnetic coupling from Phase-B and Phase-C in a current measurement by the sensor array.

### TECHNICAL FIELD

This invention relates to high voltage electric power systems and, more particularly, to a non-contact current sensor array for high voltage electric power lines providing analog suppression of magnetic coupling from neighboring conductors.

### BACKGROUND

Non-contact current sensors can be used to measure electric currents flowing in high voltage electric power lines. They have the advantages of being physically disconnected from the measured power line and set back a sufficient distance to be sufficiently isolated without involving high voltage insulators in contact with the power line, as used in many conventional current transformers. These features can lead to great economic advantages in manufacturing, installation, operation and maintenance of current measurement systems for high voltage circuits. However, conventional non-contact current sensors have not been widely adopted in practice mainly because they experience high levels of interference from the currents flowing in neighboring wires, as typically occurs in the case of electric power transmission or distribution circuits where three-phase wires are used to transfer power. In a typical high voltage power line, the phase conductors are located sufficiently close to each other to produce mutual coupling among neighboring phase conductor resulting in “phantom faults” where a fault occurring in one phase conductor shows up on other one or two phase in certain levels. This effect may also occur during normal operation reducing the accuracy of the current measurement, which has inhibited the adoption of conventional non-contact current sensors.

Non-contact current sensors have been used in certain applications to indicate that a fault has occurred in a section of three-phase electric power line. The pole-mounted fault indicator offered by Streamer Electric is an example of this type of device. However, this type of non-contact current sensor only indicates that the three-phase power line has experienced without identifying which phase experienced the fault or a precise measurement of the fault current. U.S. Pat. No. 7,191,074 addresses the mutual coupling problem through digital calculation. This approach requires a processor to perform the digital calculations, which adds cost and complexity to the system.

### SUMMARY

The needs described above are met in a non-contact electric current sensor array providing analog suppression of mutual coupling from neighboring conductors. For a high voltage electric power line including phase conductors Phase-A, Phase-B and Phase-C, the sensor array for Phase-A current measurement includes a primary sensor in transverse alignment with Phase-A, a first ancillary sensor in radial alignment with Phase-B, a second ancillary sensor in radial alignment with Phase-C. The primary sensor, first ancillary sensor, and second ancillary sensor are electrically connected in series with respective winding turns selected to substantially cancel out magnetic coupling from Phase-B and Phase-C in a current measurement by the sensor array. As a result, the current measurement of the sensor array is proportional to electric current in Phase-A with analog suppression of magnetic coupling from the neighboring Phase-B and Phase-C.

In a representative embodiment, the primary sensor comprises N winding turns, the first ancillary sensor has K2*N winding turns, the second ancillary sensor has K3*N winding turns, where the turns ratios K2 and K3 are determined based on positions and alignment of the sensors with respect to the phase conductors.

It will be understood that specific embodiments may include a variety of features in different combinations, and that all of the features described in this disclosure, or any particular set of features, need not be included in a particular embodiment. The specific techniques and structures for implementing particular embodiments of the invention and accomplishing the associated advantages will become apparent from the following detailed description of the embodiments and the appended drawings and claims.

### BRIEF DESCRIPTION OF THE FIGURES

The numerous advantages of the invention may be better understood with reference to the accompanying figures in which:

FIG. 1 is a conceptual illustration of a non-contact sensor array installed adjacent to a three-phase electric power line.

FIG. 2 is a conceptual illustration of a representative electric current sensor.

FIG. 3 is a conceptual illustration of electric current sensor alignment.

FIG. 4 is a conceptual illustration of a sensor array.

FIG. 5 is an electric schematic diagram of the sensor array.

FIG. 6 is an alignment diagram of a first example sensor array.

FIG. 7 is an alignment diagram of a second example sensor array.

FIG. 8 is a flow chart illustrating a procedure for making and using the non-contact sensor array.

### DESCRIPTION OF ILLUSTRATIVE EMBODIMENTS

Embodiments of the invention include a non-contact current sensor array for high voltage electric power lines providing analog suppression of magnetic coupling from neighboring conductors. In the example embodiments illustrated in the figures, the non-contact sensor array measures magnetic coupling proportional to the current in a selected phase conductor (e.g., Phase-A) of a three-phase power line, while suppressing magnetic coupling from the other phase conductors of the power line (e.g., Phase-B and Phase-C). The sensor array includes a primary sensor in transverse alignment with Phase-A, a first ancillary sensor in radial alignment with Phase-B, and a second ancillary sensor in radial alignment with Phase-C. The primary sensor, first ancillary sensor, and second ancillary sensor are electrically connected in series with respective winding turns selected to substantially cancel out magnetic coupling from Phase-B and Phase-C in a current measurement by the sensor array. The current measurement by the sensor array is proportional to electric current in Phase-A with analog suppression of mutual magnetic coupling from the neighboring phases. As a result, the sensor array produces a much more accurate measurement of the Phase-A current than prior non-contact sensors.

Although only the Phase-A sensor array is illustrated as the measured phase, a similar sensor array may be installed for each phase conductor. In addition, ancillary sensors used to cancel out magnetic coupling are not limited to the phase conductors of the same power line. For example, additional ancillary sensors could be used to cancel out magnetic coupling from one or more phases of another nearby power line. This might be useful, for example, when multiple three-phase power lines are connected to the same support structure.

The non-contact sensor arrays are a low-cost, easy to implement approach to providing more accurate phase current measurements, which will help foster widespread adoption throughout electric utility systems. The accurate phase current measurements will allow electric utilities to take a variety of automatic and manual response actions based on the accurate phase currents measured by the non-contact sensor arrays. Representative response actions are described in U.S. Pat. No. 7,191,074, which is incorporated by reference.

For example, a spike in a phase current may indicate a faulted phase that requires the operation of one or more circuit interrupters to isolate the fault. Alternatively, persistent but not spiking high phase currents may indicate a high system load causing a voltage drop that can be alleviated by the operation of voltage support equipment, such as capacitor banks, voltage regulators or other voltage sag support equipment. Other response devices may also be activated, such as transmission line interconnection switches, strategically placed synchronous condensers, strategically placed diesel power generation stations, small hydroelectric power stations, battery and other power storage devices, fuel cells, load management, interruptable load and load shedding switches. These types of response actions are typically coordinated by a control center, where the phase currents measured by the sensor arrays are recorded, analyzed and reported over time with a reporting system. This type of system can determine, for example, whether current overload or power line physical conditions are getting worse or have reached a critical point.

Generally, more accurate phase current monitoring in critical locations improves the operation of the response equipment, avoids unnecessary and disruptive response actions in favor of more accurate and effective response actions, and generally results in the delivery of more reliable and higher quality power service. This type of system will also help to identify critical locations in which voltage support equipment is needed, as well as providing a very effective means for early detection and avoidance of cascading power outages. The system will also be an effective mechanism for identifying other types of potentially damaging power system disturbances affecting phase currents, such as dynamic generation station oscillation, reactive power circulation, intermittent abnormal load behavior, lightening strikes, and so forth.

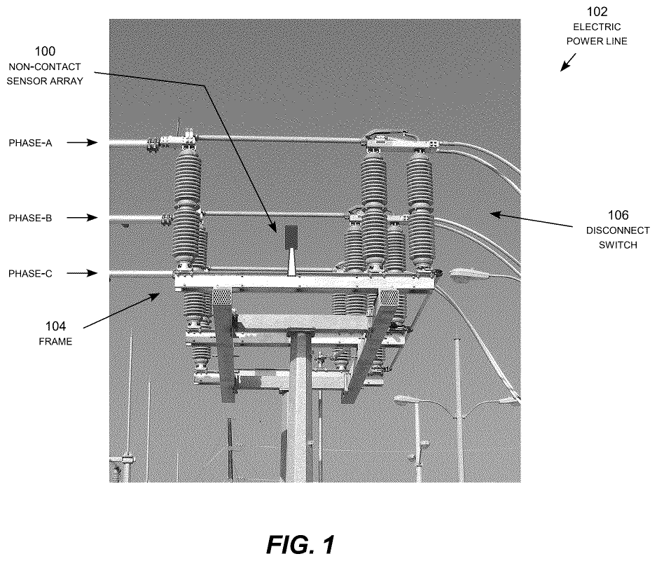

FIG. 1 is a conceptual illustration of a non-contact sensor array 100 installed adjacent to a three-phase electric power line 102 including conductors Phase-A, Phase-B and Phase-C. In this example, the non-contact sensor array 100 is installed directly under Phase-A and configured to measure the electric current carried by Phase-A while suppressing magnetic coupling from Phase-B and Phase-C. Although only the Phase-A non-contact sensor array is shown in this example, a similar sensor array may be installed for each of the other phase conductors. As the sensor arrays mitigate mutual coupling from the neighboring power lines, each sensor array determines the current on its associated phase much more accurately than prior non-contact sensors.

In the example shown in FIG. 1, the non-contact sensor array 100 is installed on a frame 104 supporting a disconnect switch 106 of the power line 102. This is an advantageous place to locate the sensor array 100 because the frame 104 provides a convenient mounting location well within the electro-magnetic field of the power line 102. In this location, the sensor array 100 experiences strong magnetic coupling with Phase-A, while also experiencing significant mutual coupling from Phase-B and Phase-C. The sensor array 100 provides analog suppression of this mutual coupling. The specific location of the sensor array 100 is only an example location to illustrate the principles of the invention. The non-contact sensor may also be connected to the support structures for other types of electric power devices, such as power line poles, circuit breakers, tie switches, transformers, voltage regulators, etc.

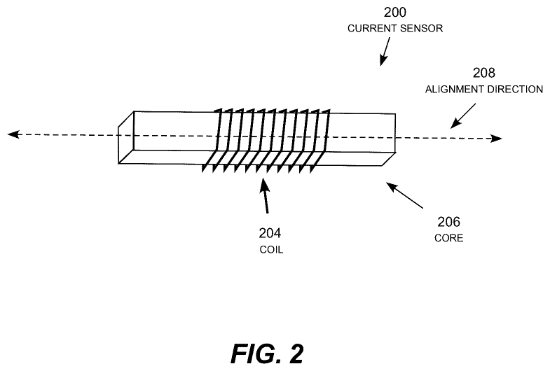

FIG. 2 is a conceptual illustration of a representative electric current sensor 200, which includes a wire coil 204 wound around a core 206. The coil encircles the principal direction of magnetic flux propagation through the core, which defines the alignment direction 208 of the sensor 200. For an elongated core 206 as shown in FIG. 2, the alignment direction 208 is typically the elongated dimension of the core. The coil 204 may be fabricated from a wire of any suitable electric conductor, such as copper or aluminum, The core 206 may be fabricated from any suitable magnetic flux conductor. For example, the core may be iron, which is known for high magnetic coupling. The core need not have a square cross-section as shown in FIG. 2, but may have any suitable shape, such as a rectangular cross-section, circular cross-section, etc. The current sensor may, for example, be a linear section of Rogowski coil, which may be modified to have an iron core to improve magnetic coupling.

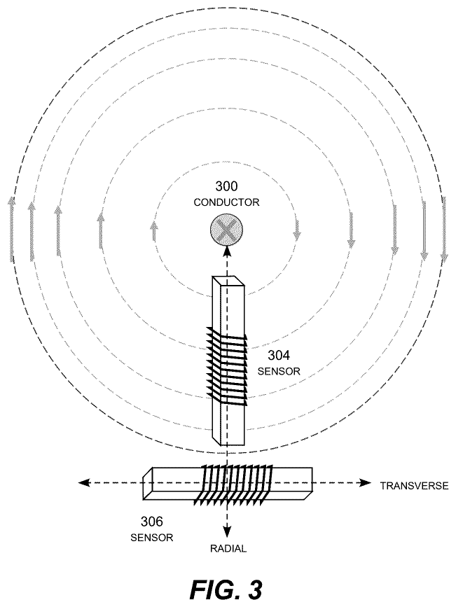

FIG. 3 is a conceptual illustration of electric current sensor alignment with respect to an electric conductor 300. The sensor 304 is in radial alignment the conductor 300, which inherently suppresses magnetic coupling between the sensor and the conductor. Theoretically, a linear sensor in precise radial alignment with its respective phase conductor has zero magnetic coupling with the conductor. The sensor 306 is in transverse alignment the conductor 300, which inherently allows magnetic coupling between the sensor and the conductor. Theoretically, a linear sensor in precise transverse alignment with its respective phase conductor has maximum magnetic coupling with the conductor.

As theoretically perfect alignment is not achievable in practice, the terms “radial alignment” and “transverse alignment” accommodate a practical offset from theoretically perfect alignment, which ultimately shows up in the accuracy of the current measurement of the sensor array. In addition, system designers may intentionally build an amount of offset into the sensor alignment and take this offset into account in the determination of the winding turns ratios. The terms “radial alignment” and “transverse alignment” also accommodate this type of intentional offset. While this type of variation increases the complexity of the computations, it does not alter the principles of the invention illustrated by the simplified examples in the representative embodiments.

In addition, for two otherwise identical sensors at the same alignment and distance to a conductor, the relative number of winding turns, also referred to as the turns ratio, determines the relative magnitude of the magnetic coupling. The number of winding turns is also subject to a practical offset from theoretically perfect number of winding turns, which ultimately shows up in the accuracy of the current measurement of the sensor array. For a three-phase sensor array, the relative number of winding turns are selected to substantially cancel out the magnetic coupling from the neighboring phases (e.g., Phase-B and Phase-C), leaving the magnetic coupling of the array substantially proportional to the current of the measured phase (e.g., Phase-A). The term “substantial” for this purpose may be construed to mean a 90% reduction in the magnetic coupling interference caused by the neighboring phases on the current measurement of the measured phase.

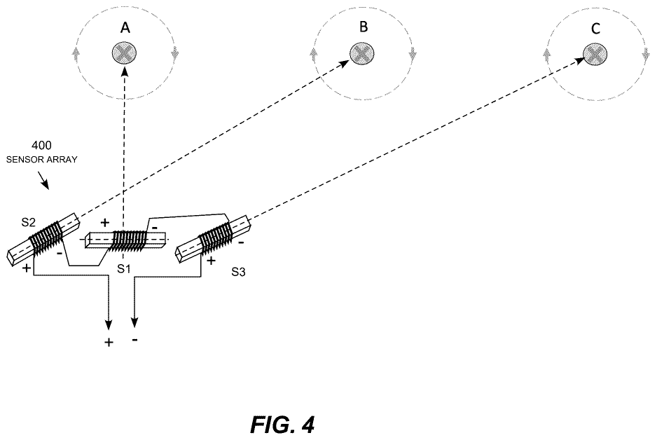

FIG. 4 is a conceptual illustration of a sensor array 400, which includes a primary sensor S1, a first ancillary sensor S2, and a second ancillary sensor S3. The primary sensor S1 is in transverse alignment with Phase-A, the first ancillary sensor S2 is in radial alignment with Phase-B, and the second ancillary sensor S3 is in radial alignment with Phase-C. The primary sensor S1 is in transverse alignment with Phase-A to maximize its magnetic coupling with the Phase-A conductor. With this alignment, however, the primary sensor S1 also experiences significant magnetic coupling with Phase-B and Phase-C. The ancillary sensors S2 and S3 are configured to substantially cancel out the unwanted magnetic coupling with these neighboring phases.

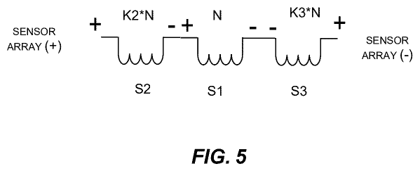

The first ancillary sensor S2 is in radial alignment with Phase-B to suppress magnetic coupling with Phase-B for sensor S2, while allowing magnetic coupling with Phase-A and Phase-C. Similarly, the second ancillary sensor S3 is aligned radially to the Phase-C conductor to suppress magnetic coupling with Phase-C for sensor S3, while allowing magnetic coupling with Phase-A and Phase-B. To cancel out magnetic coupling of the primary sensor S1 with Phase-B and Phase-C, the sensors S1, S2 and S3 are connected in series with the polarities of the sensors selected as shown in FIG. 4. That is, the ancillary sensors S2 and S3 are connected with opposing polarity. FIG. 5 is an electric schematic diagram of the sensor array also showing the polarity of the sensors in the series connection.

To obtain the desired magnitudes for cancellation, S1 has N coil turns, while S2 has K2*N coil turns (i.e., K2 is the turns ratio of S2 with respect to S1), and S3 has K3*N coil turns (i.e., K3 is the turns ratio of S3 with respect to S1). The turns ratios K2 and K3 may be determined based on the physical positions and alignment of the sensors with respect to the phase conductors.

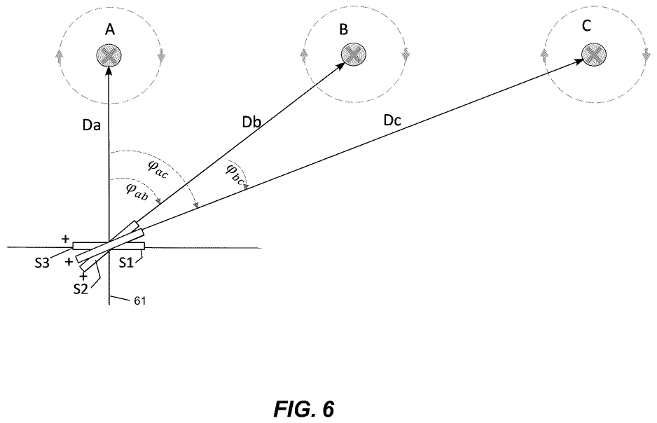

FIG. 6 is an alignment diagram of an example sensor array to illustrate the theoretical basis of the winding turns determination. To simplify this example to illustrate the underlying principles, sensors S1, S2 and S3 are considered to be at the same location in a two-dimensional frame of reference. The normal (perpendicular) vector 61 from sensor S1 is shown for reference.

The current measured by the sensor array I(array) is determined by the following equation, where I1, I2 and I3 and the currents of sensors S2, S2 and S3, respectively, and the formula reflects the sensor polarity connection shown in FIGS. 4 and 5:

$$I ( array ) = I 1 + I 2 - I 3$$

Substituting in the magnetically induced current values produces the sensor array current I(array):

$$I ( array ) = N \{ {I}_{a} ( \frac{1}{{D}_{a}} + \frac{K 2}{{D}_{a}} sin {φ}_{a b} - \frac{K 3}{{D}_{a}} sin {φ}_{a c} ) + {I}_{b} ( \frac{1}{{D}_{b}} cos {φ}_{a b} - \frac{K 3}{{D}_{b}} sin {φ}_{b c} ) + {I}_{c} ( \frac{1}{{D}_{c}} cos {φ}_{b c} - \frac{K 2}{{D}_{c}} sin {φ}_{b c} ) \}$$

The following values for the turns ratios K2 and K3 are derived to eliminate magnetic coupling from Phase B and Phase C:

$$K 2 = \frac{cos {φ}_{b c}}{sin {φ}_{b c}}$$

$$K 3 = \frac{cos {φ}_{a b}}{sin {φ}_{b c}}$$

The resulting expression for the sensor array current I(array) is proportional to the Phase-A current (Ia) without contribution from Phase-B or Phase C:

$$I ( array ) = N * {I}_{a} ( \frac{1}{{D}_{a}} + \frac{cos {φ}_{b c} sin {φ}_{a b}}{{D}_{a} sin {φ}_{b c}} - \frac{cos {φ}_{a b} sin {φ}_{a c}}{{D}_{a} sin {φ}_{b c}} )$$

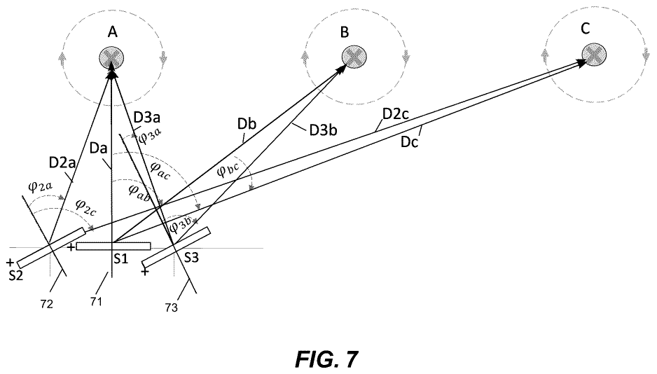

FIG. 7 is an alignment diagram of a second example sensor array in which the sensors are spaced apart in a two-dimensional frame of reference. The normal (perpendicular) vectors 71 from sensor S1, 72 from sensor S2, and 73 from sensor S3 are shown for reference. The current measured by the sensor array I(array) is determined by the following equation, where I1, I2 and I3 and the currents of sensors S2, S2 and S3, respectively:

$$I ( array ) = I 1 + I 2 - I 3$$

Substituting in the magnetically induced current values produces I(array):

$${I}_{( a r r a y )} = N \{ {I}_{a} ( \frac{1}{{D}_{a}} + \frac{K 2}{{D}_{2 a}} cos {φ}_{2 a} - \frac{K 3}{{D}_{3 a}} cos {φ}_{3 a} ) + {I}_{b} ( \frac{1}{{D}_{b}} cos {φ}_{a b} - \frac{K 3}{{D}_{3 b}} cos {φ}_{3 b} ) + {I}_{c} ( \frac{1}{{D}_{c}} cos {φ}_{a c} - \frac{K 2}{{D}_{2 c}} cos {φ}_{2 c} ) \}$$

The following values for the turns ratios K2 and K3 are derived to eliminate magnetic coupling from Phase B and Phase C:

$$K 2 = \frac{{D}_{2 c} cos {φ}_{a c}}{{D}_{c} cos {φ}_{2 c}}$$

$$K 3 = \frac{{D}_{3 b cos {φ}_{a b}}}{{D}_{b} cos {φ}_{3 b}}$$

The resulting expression for the sensor array current I(array) is proportional to the Phase-A current (Ia) without contribution from Phase-B or Phase C:

$${I}_{( a r r a y )} = N * {I}_{a} ( \frac{1}{{D}_{a}} + \frac{{D}_{2 c} cos {φ}_{a c} cos {φ}_{2 a}}{{D}_{2 a} {D}_{c} cos {φ}_{2 c}} - \frac{{D}_{3 b} cos {φ}_{a b} cos {φ}_{3 a}}{{D}_{3 a} {D}_{b} cos {φ}_{3 b}} )$$

Those skilled in the art will be able to derive the turns ratios for other physical arrangements of phase conductors and sensors. The approach can be generally applied to other layouts of a three-phase lines, including vertical, horizontal, triangle, etc. Additional conductors may also be considered. For every additional neighboring wire involved, one more ancillary sensor can be added to eliminate its coupling effect from the primary sensor.

Although FIG. 7 shows the sensors spaced apart horizontally, they may alternatively or additionally be spaced vertically. In addition, the spacing between the sensors may be, but need not be, the same. It should also be noted that representative examples are shown in a two-dimensional frame of reference to simplify the computations illustrating the principles of the invention. A practical system may be arranged in a 3-dimensional frame of references with third dimensions of alignment and distance to be taken into consideration. These types of variations complicate the mathematics without altering the principles of the invention illustrated by the representative examples.

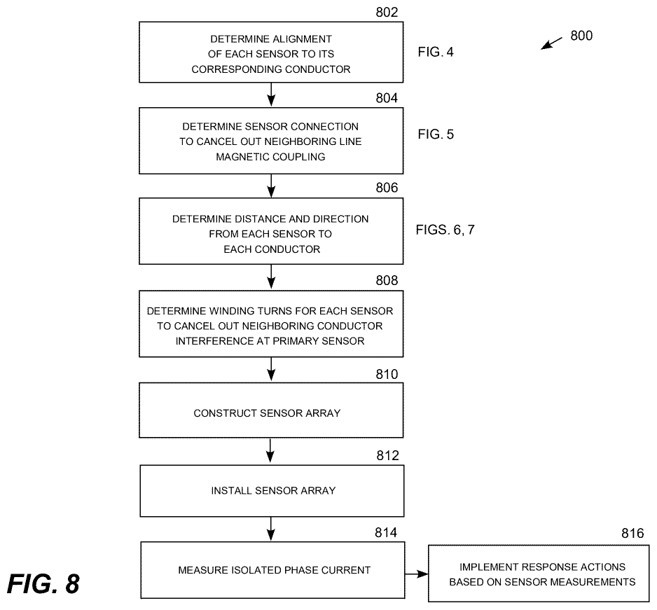

FIG. 8 is a flow chart illustrating a process 800 for making and using a non-contact sensor assembly. In step 802, the sensor alignment is determined. A representative example is shown in FIG. 4 In this example, the primary sensor S1 is positioned well within the electromagnetic field of its associated conductor, Phase-A in this example. The primary sensor S1 is aligned transverse to Phase-A to experience the greatest magnetic coupling with Phase-A. With this alignment, S1 also picks up unwanted magnetic coupling interference from Phase-B and Phase-C.

To cancel out the magnetic coupling interference from Phase-B and Phase-C, a first ancillary sensor S2 is positioned adjacent to S1 and aligned radially with (pointed towards) its associated conductor Phase-B. Pointing the core of the sensor S2 toward Phase-B excludes magnetic coupling from Phase-B, causing S2 to only pick up magnetic coupling with Phase-A and Phase-C. Similarly, a second ancillary sensor S3 is positioned adjacent S1 and aligned radially with its associated conductor Phase-C. Pointing the core of the sensor S3 toward Phase-C excludes magnetic coupling from Phase-C, causing S3 to only pick up magnetic coupling with Phase-A and Phase-B.

Step 802 is followed by step 804, in which the electrical connections of the sensors S1, S2 and S3 is determined to cause cancellation of the mutual coupling from Phase-B and Phase C at the primary sensor S1. In this example, the sensors S1, S2 and S3 are connected in series with the polarities shown in FIGS. 4 and 5, in which the first and second ancillary sensors S2 and S3 are connected with opposing polarities.

Step 804 is followed by step 806, in which the physical layout of the sensor system is determined. This includes determining the distance and direction from each sensor to each phase conductor. Representative examples are illustrated in FIGS. 6 and 7.

Step 806 is followed by step 808, in which winding turns are determined for the sensors S1, S2 and S3 to cancel out the magnetic coupling interference at the primary sensor S1 caused by magnetic coupling with Phase-B and Phase-C. The turns ratios for the primary sensor S1 to N as appropriate to receive a sufficient magnetic coupling signal with the Phase-A. The turns ratios K2 and K3 for the ancillary sensors S2 and S3 can be determined directly from the physical conductor and sensor layout, as described previously for the representative examples shown in FIGS. 6 and 7.

Step 808 is followed by step 810, in which the sensors S1, S2 and S3 are constructed with the determined number of turns. Each sensor may be substantially the same except for the number of windings. The sensors are electrically connected in series with the desired polarities as shown in FIGS. 4 and 5, and aligned as shown in FIG. 4, to construct the sensor array. Because the sensor alignment is determined by the physical layout of the sensors and conductors, the sensor array can be fabricated in the lab prior to installation in the field.

Step 810 is followed by step 812, in which the sensors array is installed at desired position and alignment. Step 812 is followed by step 814, in which the sensors array measures the Phase-A current with the magnetic coupling interference from Phase-B and Phase-C canceled out. The interference is cancelled out on an analog basis by the sensor array without the need for digital computation.

Step 814 is followed by step 816, in which the electric utility system using the sensor array takes response actions based on the current measurement of the sensor array. For example, a switch may open to disconnect a faulted phase as determined by the sensor array. The system may also issue alarms and operate other equipment in response to the current measurement, such as operating a tie switch, voltage regulator, capacitor bank, and so forth.

The specific sensor positioning for the example power line shown in the figures only provided as examples to illustrate the principles of the invention. The sensors may be positioned differently provided that each ancillary sensor is pointed radially toward its respective conductor and the number of winding turns for the sensors are determined to substantially eliminate magnetic coupling interference from the other conductors in the sensor array current measurement.

Moreover, the 3-phase power line is only one example of the number of conductors that may be taken into account by the sensor assembly. The inventive process may be employed for a larger number of conductors as long as there is at least one sensor for each conductor to be taken into consideration.

The phase naming convention is not limiting, as any phase may be assigned any phase name as a matter of descriptive convenience. The specific dimensions illustrated in the figures is for conceptual purposes and not shown to scale.

The foregoing relates only to the exemplary embodiments of the present invention, and numerous changes may be made therein without departing from the spirit and scope of the invention as defined by the following claims.

The invention claimed is:

1. A non-contact electric current sensor array for a high voltage electric power line comprising phase conductors Phase-A, Phase-B and Phase-C, comprising:
a primary sensor in transverse alignment with Phase-A;
a first ancillary sensor in radial alignment with Phase-B;
a second ancillary sensor in radial alignment with Phase-C;
wherein the primary sensor, first ancillary sensor, and second ancillary sensor are electrically connected in series with respective winding turns selected to substantially cancel out magnetic coupling from Phase-B and Phase-C in a current measurement of Phase-A by the sensor array.

2. The non-contact electric current sensor array of claim 1, wherein the first ancillary sensor is electrically connected with opposing polarity to the second ancillary sensor.

3. The non-contact electric current sensor array of claim 1, wherein the current measurement by the sensor array is proportional to electric current in Phase-A.

4. The non-contact electric current sensor array of claim 1, wherein:
the primary sensor comprises N winding turns;
the first ancillary sensor comprises K2*N winding turns;
the second ancillary sensor comprises K3*N winding turns;
wherein K2 and K3 are determined based on positions and alignment of the sensors with respect to the phase conductors.

5. The non-contact electric current sensor array of claim 1, wherein the phase conductors are arranged horizontally.

6. The non-contact electric current sensor array of claim 1, wherein the phase conductors are arranged vertically.

7. The non-contact electric current sensor array of claim 1, wherein the phase conductors are arranged in a triangle.

8. A high voltage power line including a power line support, comprising:
a non-contact electric current sensor array for supported by the power line support comprising phase conductors Phase-A, Phase-B and Phase-C, including a primary sensor in transverse alignment with Phase-A, a first ancillary sensor in radial alignment with Phase-B, and a second ancillary sensor in radial alignment with Phase-C;
wherein the primary sensor, first ancillary sensor, and second ancillary sensor are electrically connected in series with respective winding turns selected to substantially cancel out magnetic coupling from Phase-B and Phase-C in a current measurement of Phase-A by the sensor array.

9. The high voltage power line of claim 8, wherein the power line support comprises a frame supporting a disconnect switch of the power line.

10. The high voltage power line of claim 8, wherein the first ancillary sensor is electrically connected with opposing polarity to the second ancillary sensor.

11. The high voltage power line of claim 8, wherein the current measurement by the sensor array is proportional to electric current in Phase-A.

12. The high voltage power line of claim 8, wherein:
the primary sensor comprises N winding turns;
the first ancillary sensor comprises K2*N winding turns;
the second ancillary sensor comprises K3*N winding turns;
wherein K2 and K3 are determined based on positions and alignment of the sensors with respect to the phase conductors.

13. The high voltage power line of claim 8, wherein the phase conductors are arranged horizontally.

14. The high voltage power line of claim 8, wherein the phase conductors are arranged vertically.

15. The high voltage power line of claim 8, wherein the phase conductors are arranged in a triangle.
